(19) United States
(12) Patent Application Publication
(10) Pub. No.: US 2009/0269920 A1
(43) Pub. Date: Oct. 29, 2009

(54) METHOD OF FORMING INTERCONNECTION LINE AND METHOD OF MANUFACTURING THIN FILM TRANSISTOR SUBSTRATE

(76) Inventors: Jeong-Min PARK, Seoul (KR); Hi-Kuk Lee, Yongin-si (KR); Doo-Hee Jung, Seoul (KR)

Correspondence Address: Haynes and Boone, LLP;IP Section, 2323 Victory Avenue, SUITE 700, Dallas, TX, 75219, US

(21) Appl. No.: 12/420,783

(22) Filed: Apr. 8, 2009

(30) Foreign Application Priority Data
Apr. 24, 2008 (KR) 10-2008-0038303

(51) Int. Cl. H01L 21/336; H01L 23/52

(52) U.S. Cl. 438/618; 257/E21.411; 257/E23.141

(57) ABSTRACT

A method of forming an interconnection line and a method of manufacturing a thin film transistor substrate are provided in accordance with one or more embodiments of the present invention. The method of forming an interconnection line in accordance with one or more embodiments of the present invention includes preparing a substrate, forming a lower organic layer and an upper organic layer on the substrate in lamination, forming trenches in parts of the upper organic layer and the lower organic layer, forming a lower interconnection layer in the trenches formed in parts of the lower organic layer, removing the upper organic layer, and filling the trenches formed in parts of the lower organic layer with an upper interconnection layer.

### CROSS-REFERENCE TO RELATED APPLICATION

This application claims priority to and the benefit of Korean Patent Application No. 10-2008-0038303 filed on Apr. 24, 2008, in the Korean Intellectual Property Office, the disclosure of which is incorporated herein by reference in its entirety.

### BACKGROUND

1. Technical Field

One or more embodiments of the present invention generally relate to a method of forming an interconnection line and a method of manufacturing a thin film transistor substrate. More particularly, one or more embodiments of the present invention relate to a method of forming an interconnection line and a method of manufacturing a thin film transistor substrate to achieve a low-resistance characteristic by forming the interconnection line with a sufficient thickness using a trench structure.

2. Description of the Related Art

With the development of mass production and improved technology, deficiencies of liquid crystal display (LCD), such as narrow viewing angle, low response speed, high manufacturing cost, and the like, have seen rapid improvement. Concurrently, advantages thereof, such as high resolution, light weight, small size, and low power consumption, etc. have been highlighted as important technical requirements in a changing technical environment marked by the convergence of consumer electronics and ubiquitous communication. Accordingly, a Braun tube type display has been rapidly replaced by LCD.

Recently, as the demand for large-screen and high-definition LCD has risen, the length of an interconnection line has been increased, and the line width thereof has been decreased. As the length of the interconnection line is increased, the resistivity and capacitance of the interconnection line are abruptly increased, resulting in image distortion due to an RC delay phenomenon. RC delay phenomenon causes signal delay and is measured by a time constant, which is determined by a multiplication of a self resistance R and a parasitic capacitance C of the interconnection line (i.e., γ=RC). Increased RC delay is generated due to an increase in the parasitic capacitance C, which corresponds to an area of the interconnection line, as the length of the interconnection line is increased. Additionally, as the line width of the interconnection line is decreased, the resistance R is increased, resulting in increased leakage current. In this case, it is required to apply a relatively high supply voltage to the interconnection line, and this causes increased power consumption. Accordingly, in order to prevent an increase in the resistance R, it is preferable to thicken the interconnection line instead of reducing the line width of the interconnection line, so that the image distortion due to the signal delay and the increase in power consumption due to the leakage current are suppressed.

However, if a thick interconnection line is formed on the substrate, stress due to lattice mismatch between the substrate and the interconnection line is generated on a boundary surface between them, and this causes the substrate to be warped or a thin film to be broken. According to the conventional method of manufacturing liquid crystal display, in order to solve this, a thin lower conductive layer that serves as a seed layer is formed on the substrate through a first patterning, a thick organic layer is formed on the lower conductive layer, and then a trench is formed through a second patterning of the organic layer. Then, an upper conductive layer is formed to fill in the trench, so that a desired thickness of an interconnection pattern is formed on the substrate. As described above, according to the conventional method of manufacturing liquid crystal display, two photo processes are required, and thus process work and cost are increased. Also, since it is required to form a trench for forming the upper conductive layer on the lower conductive layer, high resolution is required during patterning of the organic layer. In addition, in consideration of various kinds of alignment margins, resolution that is higher than the limiting resolution of the current process equipment is required during patterning of the organic layer.

### SUMMARY

Accordingly, one or more embodiments of the present invention may solve the above-mentioned problems occurring in the prior art, and provide a method of forming an interconnection line and a method of manufacturing a thin film transistor substrate to reduce manufacturing time and cost by shortening the process of forming a thick interconnection line from the two photo processes of the conventional method to one photo process.

One or more embodiments of the present invention also provide a method of forming an interconnection line and a method of manufacturing a thin film transistor substrate to prevent a substrate from being warped or to prevent a thin film transistor from being broken even if an interconnection line is formed with a desired thickness.

One or more embodiments of the present invention also provide a method of forming an interconnection line and a method of manufacturing a thin film transistor substrate to prevent an increase in RC delay and an increase in leakage current caused by a decrease in the line width and an increase in the length of an interconnection line.

One or more embodiments of the present invention will be set forth in the description which follows. Other embodiments of the present invention will become apparent to those having ordinary skill in the art upon examination of the following embodiments or may be understood from practice of the invention.

One or more embodiments of the present invention provide a method of forming an interconnection line, which includes preparing a substrate; forming a lower organic layer and an upper organic layer on the substrate in lamination; forming trenches in parts of the upper organic layer and the lower organic layer; forming a lower interconnection layer in the trenches formed in parts of the lower organic layer; removing the upper organic layer; and filling the trenches formed in parts of the lower organic layer with an upper interconnection layer.

In accordance with an embodiment of the present invention, the lower organic layer and the upper organic layer may be formed of material that can be developed.

In accordance with an embodiment of the present invention, the material for forming the lower organic layer may have a higher development speed than a development speed of the material for forming the upper organic layer.

In accordance with an embodiment of the present invention, the material for forming both the lower organic layer and the upper organic layer may include a positive type photosensitive material.

In accordance with an embodiment of the present invention, the material for forming both the lower organic layer and the upper organic layer may include a negative type photosensitive material.

In accordance with an embodiment of the present invention, the material for forming the lower organic layer may include a non-photosensitive material, and the material for forming the upper organic layer may include a photosensitive material.

In accordance with an embodiment of the present invention, the material for forming the lower organic layer may include acrylic resin, and the material for forming the upper organic layer may include novolac resin.

In accordance with an embodiment of the present invention, the forming of the trenches may include forming a first trench by removing a part of the upper organic layer; and forming a second trench by removing a part of the lower organic layer that is exposed through the first trench.

In accordance with an embodiment of the present invention, the first trench may have a width that is uniform or becomes wider with increasing depth.

In accordance with an embodiment of the present invention, the second trench may have a width that becomes wider with increasing depth.

In accordance with an embodiment of the present invention, the first trench may have a width that becomes narrower with increasing depth, and the second trench may have a width that becomes narrower with increasing depth.

In accordance with an embodiment of the present invention, the filling of the trenches formed in parts of the lower organic layer may include plating the upper interconnection layer onto the lower interconnection layer formed on a bottom of the trenches.

One or more embodiments of the present invention provide a method of forming an interconnection line, which includes preparing a substrate; forming a lower inorganic layer and an upper organic layer on the substrate in lamination; forming trenches in parts of the upper organic layer and the lower inorganic layer; forming a lower interconnection layer in the trenches formed in parts of the lower inorganic layer; removing the upper organic layer; and filling the trenches formed in parts of the lower inorganic layer with an upper interconnection layer.

One or more embodiments of the present invention provide a method of manufacturing a thin film transistor substrate, which includes preparing a transparent substrate; forming a lower organic layer and an upper organic layer on the substrate in lamination; forming trenches in parts of the upper organic layer and the lower organic layer; forming a lower interconnection layer in the trenches formed in parts of the lower organic layer; removing the upper organic layer; filling the trenches formed in parts of the lower organic layer with an upper interconnection layer; and forming a thin film transistor using the lower interconnection layer and the upper interconnection layer formed on the trenches as an interconnection line thereof.

In accordance with an embodiment of the present invention, the lower organic layer and the upper organic layer may be formed of material that can be developed.

In accordance with an embodiment of the present invention, the material for forming the lower organic layer may have a higher development speed than a development speed of the material for forming the upper organic layer.

In accordance with an embodiment of the present invention, the material for forming both the lower organic layer and the upper organic layer may include a positive type photosensitive material or a negative type photosensitive material.

In accordance with an embodiment of the present invention, the material for forming the lower organic layer may include a non-photosensitive material, and the material for forming the upper organic layer may include a photosensitive material.

In accordance with an embodiment of the present invention, the forming of the trenches may include forming a first trench by removing a part of the upper organic layer; and forming a second trench by removing a part of the lower organic layer that is exposed through the first trench.

In accordance with an embodiment of the present invention, the first trench may have a width that is uniform or becomes wider with increasing depth.

In accordance with an embodiment of the present invention, the second trench may have a width that becomes wider with increasing depth.

In accordance with an embodiment of the present invention, the filling of the trenches formed in parts of the lower organic layer may include plating the upper interconnection layer onto the lower interconnection layer formed on a bottom of the trenches.

### BRIEF DESCRIPTION OF THE DRAWINGS

The above and other embodiments of the present invention will become more apparent from the following detailed description taken in conjunction with the accompanying drawings, in which:

FIGS. 1 to 4 are sectional views explaining processes of a first method of forming an interconnection line according to one or more embodiments of the present invention;

FIGS. 5 to 8 are sectional views of a substrate for explaining a second method of forming an interconnection line according to one or more embodiments of the present invention;

FIG. 9 is a sectional view of a thin film transistor substrate manufactured by a manufacturing method according to one or more embodiments of the present invention; and

FIGS. 10 to 12 are sectional views explaining processes of a method of manufacturing a thin film transistor substrate according to one or more embodiments of the present invention.

### DETAILED DESCRIPTION

Hereinafter, one or more embodiments of the present invention will be described in detail with reference to the accompanying drawings. However, the present invention is not limited to the embodiments disclosed hereinafter, but can be embodied in many diverse forms and should not be construed as being limited to the embodiments set forth herein. Rather, these embodiments are provided to assist those of ordinary skill in the art in a comprehensive understanding of the embodiments of the present invention. As such, the present invention is only defined within the scope of the appended claims. In the drawings, sizes and relative sizes of layers and areas may be exaggerated for clarity in explanation.

It will be understood that when an element or layer is referred as being “on” another element or layer, the element or layer may be located directly on another element or layer, or intervening elements or layers may be present. By contrast, when an element or layer is referred as being “directly on” another element or layer, it means that the element or layer is directly on another element or a layer without intervention of any other element or layer present. In the entire description of one or more embodiments of the present invention, the same drawing reference numerals are used for the same elements across various figures. Also, the term “and/or” includes the respective described items and any and all combinations thereof, and the term “coupled to” means that an element is electrically connected to another element.

Spatially relative wordings, such as “below,” “beneath,” “lower,” “above,” “upper,” and so forth, as illustrated in the drawings, may be used to facilitate the description of relationships between an element or constituent elements and another element or other constituent element. The spatially relative wordings should be understood as wordings that include different directions of the element in use or operation in addition to the direction illustrated in the drawings.

In the following description, one or more embodiments of the present invention will be described with reference to plane views and sectional views which are idealized schematic views of the embodiments. The form of the exemplary views may be modified due to manufacturing techniques and/or allowable errors. Accordingly, it is understood that embodiments of the present invention are not limited to their specified form as illustrated in the exemplary views, but may include changes in form being produced according to manufacturing processes. Accordingly, areas exemplified in the drawings have rough properties, and the shapes of areas exemplified in the drawings do not limit the scope of the present invention.

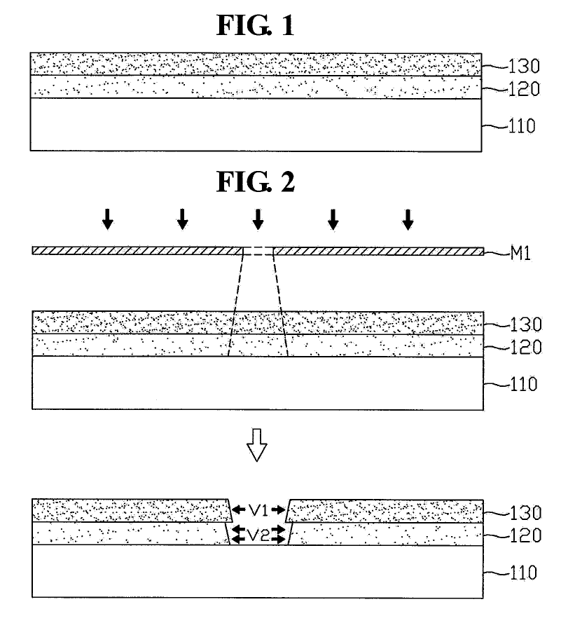

Hereinafter, a first method of forming an interconnection line according to one or more embodiments of the present invention will be described in detail with reference to FIGS. 1 to 4. Here, FIGS. 1 to 4 are sectional views explaining processes of a method of forming an interconnection line according to one or more embodiments of the present invention.

Referring to FIG. 1, a substrate 110, for example, a wafer, a glass substrate, or the like, is prepared, and a lower organic layer 120 and an upper organic layer 130 are formed on the substrate 110 in lamination. The lower organic layer 120 and the upper organic layer 130 are formed of materials that can be developed, and the lower organic layer 120 may be formed of a material having a higher development speed than that of a material of the upper organic layer 130. For example, if it is assumed that the development speed of the lower organic layer 120 is v1, and the development speed of the upper organic layer 130 is v2, v1 may be higher than v2 (v1>v2). Since the upper organic layer 130 is formed on an upper part of the lower organic layer 120, the upper organic layer 130 is first developed to form an opening part therein, and then the lower organic layer 120 is developed. In the case where the development speed v1 of the lower organic layer 120 is higher than the development speed v2 of the upper organic layer 130, opening parts having almost the same size may be formed on the upper organic layer 130 and the lower organic layer 120, even though the lower organic layer 120 is developed later and for a shorter period of time than the upper organic layer 130. The lower organic layer 120 may be formed of a photosensitive material, for example, a photoresist, or alternatively a non-photosensitive material, and the upper organic layer 130 may be formed of a photosensitive material. In one or more embodiments of the present invention, both the upper organic layer 130 and the lower organic layer 120 are formed of a positive type photosensitive material. Since a trench of the lower organic layer 120 provides a kind of wall that limits the line width and thickness of an interconnection line to be formed on the substrate 110, the lower organic layer 120 may be formed with roughly the same thickness as that of the interconnection line to be formed.

Referring to FIG. 2, trenches corresponding to regions where an interconnection line is to be formed are formed by removing parts of the upper organic layer 130 and the lower organic layer 120 through an exposure process and a development process. In the exposure process, the photosensitive layers of the upper organic layer 130 and the lower organic layer 120 may be patterned by performing exposure using a first mask M1. A developer, such as an alkaline solution of tetramethyl ammonium hydroxide (TMAH, KOH, or the like, may then be used for the development process. In the development process, the upper organic layer 130 in the exposed region is first removed to expose a part of the lower organic layer 120, and then the lower organic layer 120 is removed, so that trenches are formed in the upper organic layer 130 and the lower organic layer 120 with a specified thickness. In this case, since the upper organic layer 130 and the lower organic layer 120 are formed of a positive type photosensitive material, the exposed regions thereof are removed in order during the development process. The trench of the upper organic layer 130 is formed with slopes that make the width of the trench V1 become narrower with increasing depth. Similarly, the trench of the lower organic layer 120, which is developed through the trench of the upper organic layer 130, is formed with slopes that make the width of the trench V2 become narrower with increasing depth. Accordingly, on the slopes of the upper organic layer 130 and the lower organic layer 120, undercut occurs at the boundary surface between the upper organic layer 130 and the lower organic layer 120 due to a difference in development speed between them. That is, the width of the trench V1 of the upper organic layer 130 and the width of the trench V2 of the lower organic layer 120 become narrower in the depth direction of the trenches, and thus, on the boundary surface between the upper organic layer 130 and the lower organic layer 120, the width of the trench V2 of the lower organic layer 120 is wider than the width of the trench V1 of the upper organic layer 130.

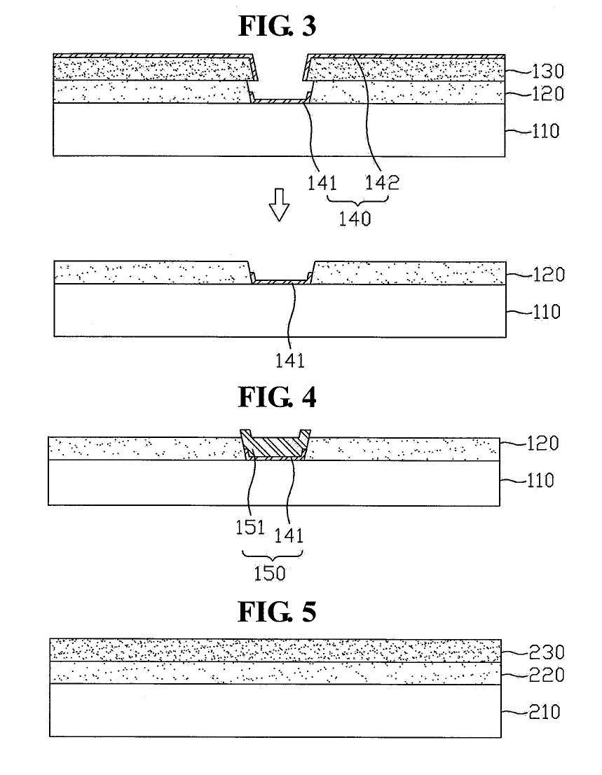

Referring to FIG. 3, on the resultant structure having the trenches of the upper organic layer 130 and the lower organic layer 120, a lower metal layer 140 is formed. Here, the lower metal layer 140 includes a lower interconnection layer 141 formed in the trench of the lower organic layer 120 and a temporary layer 142 formed on the upper organic layer 130. Then, through a lift-off process for selectively removing the upper organic layer 130, the temporary layer 142 formed on the upper organic layer 130 is separated and removed, but the lower interconnection layer 141 formed in the trench of the lower organic layer 120 remains. In the lift-off process, a stripper solution composed of about 10 wt % amine, about 20 wt % glycol, and about 70 wt % of a polar solution may be used. The lower interconnection layer 141 remaining in the trench of the lower organic layer 120 exists only in a region where the interconnection line is to be formed. Since it is required that the lower interconnection layer 141 only serves as a seed layer for smoothing the forming of a full-scale metal interconnection layer, and the temporary layer 142 formed on the upper organic layer 130 may be easily removed through the lift-off process, the lower metal layer 140 may be formed with a relatively small thickness. Also, since it is required that only the upper organic layer 130 is selectively removed during the lift-off process, the upper organic layer 130 and the lower organic layer 120 may be made of different materials. For example, the lower organic layer 120 may be formed using 5-30 wt % of acrylic group resin, 2-10 wt % of photosensitive compound, and the remaining of organic solvent, and the upper organic layer 130 may be formed using 5-30 wt % of novolac resin, 2-10 wt % of photosensitive compound, and the remaining of organic solvent. By forming the lower organic layer 120 using acrylic resin and forming the upper organic layer 130 using novolac resin, the upper organic layer 130 may be completely removed, while only a part of the lower organic layer 120 having a small thickness may be removed, with most of the lower organic layer 120 remaining, due to a difference in flaking speed between the upper organic layer 130 and the lower organic layer 120.

Referring to FIG. 4, after the lower organic layer 120 and the lower interconnection layer 141 are hardened through a heating process or a chemical process, an upper interconnection layer 151 is grown with a desired thickness on the lower interconnection layer 141 that functions as a seed layer through a plating process, so that a fairly thick interconnection line 150, which is composed of the lower interconnection layer 141 and the upper interconnection layer 151, is formed. In this case, the upper interconnection layer 151 is formed only on the lower interconnection layer 141 that functions as a seed layer, and is grown along the internal structure of the whole trench. The plating process may be an electroplating process or an electroless plating process.

As described above, in the first method of forming an interconnection line according to one or more embodiments of the present invention, a thick interconnection line 150 may be formed through one photo process. Also, since the upper interconnection layer 151 of the interconnection line 150 is formed only on a part of the substrate 110, i.e. in the trench, the interconnection line 150, even when formed with a fairly large thickness, has a low stress concentration, and thus the substrate is 110 prevented from being warped or the thin film is prevented from being broken. Also, since the sidewalls of the trench serve to disperse the stress that is increased due to the increase in the thickness of the upper interconnection layer 151 during the growing of the upper interconnection layer 151, the warping of the substrate or the breakage of the thin film can be further prevented. The lower organic layer 120 formed with the trench structure serves as a kind of buffer layer, and thus can contribute to the improvement of the quality of subsequent laminated layers (not illustrated).

Hereinafter, with reference to FIGS. 5 to 8, a second method of forming an interconnection line according to one or more embodiments of the present invention will be described in detail. Here, FIGS. 5 to 8 are sectional views explaining processes of a method of forming an interconnection line according to one or more embodiments of the present invention.

In the second method of forming an interconnection line according to one or more embodiments of the present invention, both a lower organic layer and an upper organic layer are formed of a negative type photosensitive material.

Referring to FIG. 5, a substrate 210, for example, a wafer, a glass substrate, or the like, is prepared, and a lower organic layer 220 and an upper organic layer 230 are formed on the substrate 210 in lamination. The upper organic layer 230 and the lower organic layer 220 are formed of a negative type photosensitive material.

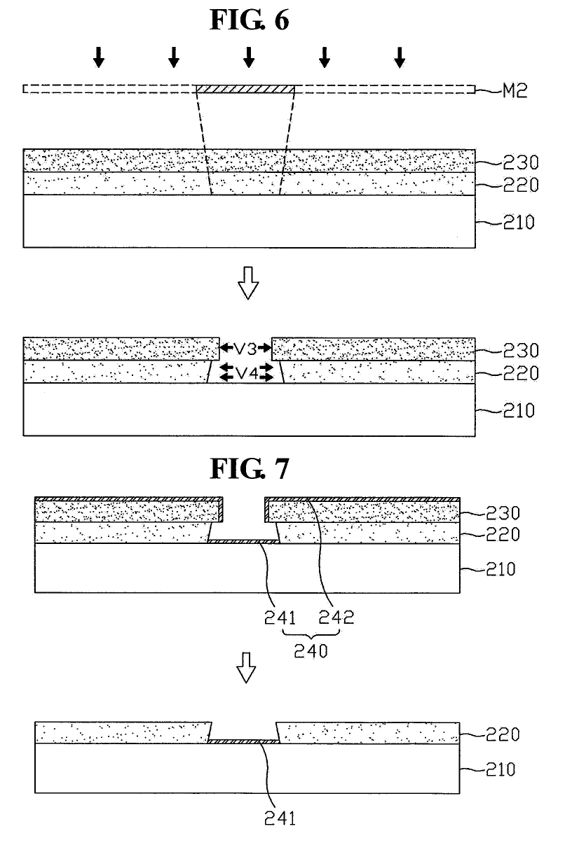

Referring to FIG. 6, trenches corresponding to regions where an interconnection line is to be formed are formed by removing parts of the upper organic layer 230 and the lower organic layer 220 through an exposure process and a development process. In the exposure process, the photosensitive layers of the upper organic layer 230 and the lower organic layer 220 may be patterned by performing exposure using a second mask M2. A developer, such as an alkaline solution of TMAH, KOH, or the like, may be used for the development process. In the development process, the upper organic layer 230 in the exposed region is first removed to expose a part of the lower organic layer 220, and then the lower organic layer 220 is removed, so that trenches are formed in the upper organic layer 230 and the lower organic layer 220 with a specified thickness. In this case, since the upper organic layer 230 and the lower organic layer 220 are formed of a negative type photosensitive material, the exposed region thereof remains during the development process. The trench formed in the upper organic layer 230 and the lower organic layer 220 may have slopes that make the width of the trench become wider with increasing depth. However, if the upper organic layer 230 is directly exposed, the sloping angle of the sidewall of the trench may become almost 90°. Accordingly, upper and lower parts of the trench of the upper organic layer 230 may have the same width V3, allowing the trench of the lower organic layer 220 to be formed with almost the same resolution as that for the trench of the upper organic layer 230. As a result, the trench of the upper organic layer 230 does not limit the width of the trench V4 of the lower organic layer 220, and thus a more precise trench can be formed on the lower organic layer 220. As described above in the first method of forming an interconnection line according to one or more embodiments of the present invention, the trench of the lower organic layer 220, which is formed through the trench of the upper organic layer 230, is formed for a somewhat shorter development time. Accordingly, in order to form the trenches of the upper organic layer 230 and the lower organic layer 220 with the same width, the lower organic layer 220 may be formed of a material having a development speed that is higher than that of a material of the upper organic layer 230. That is, if it is assumed that the development speed of the lower organic layer 220 is v3 and the development speed of the upper organic layer 230 is v4, v3 is higher than v4 (v3>v4).

Referring to FIG. 7, on the resultant structure having the trenches of the upper organic layer 230 and the lower organic layer 220, a lower metal layer 240 is formed. Here, the lower metal layer 240 includes a lower interconnection layer 241 formed in the trench of the lower organic layer 220 and a temporary layer 242 formed on the upper organic layer 230. Then, through a lift-off process for selectively removing the upper organic layer 230, the temporary layer 242 formed on the upper organic layer 230 is separated and removed, but the lower interconnection layer 241 formed in the trench of the lower organic layer 220 remains. In the lift-off process, a stripper solution composed of about 10 wt % amine, about 20 wt % glycol, and about 70 wt % of a polar solution may be used. Also, since it is required that only the upper organic layer 230 is selectively removed during the lift-off process, the upper organic layer 230 and the lower organic layer 220 may be made of different materials. For example, the lower organic layer 220 may be formed using 5-30 wt % of acrylic group resin, 2-10 wt % of photosensitive compound, 5-25 wt % of a cross-linking agent, and the remaining of an organic solvent, and the upper organic layer 230 may be formed using 5-30 wt % of novolac resin, 2-10 wt % of photosensitive compound, 5-25 wt % of a cross-linking agent, and the remaining of an organic solvent. As described above, by forming the lower organic layer 220 using acrylic resin and forming the upper organic layer 230 using novolac resin, the upper organic layer 230 is completely removed, while only a part of the lower organic layer 220 having a small thickness is removed, with most of the lower organic layer 220 remaining, due to a difference in flaking speed between the upper organic layer 230 and the lower organic layer 220.

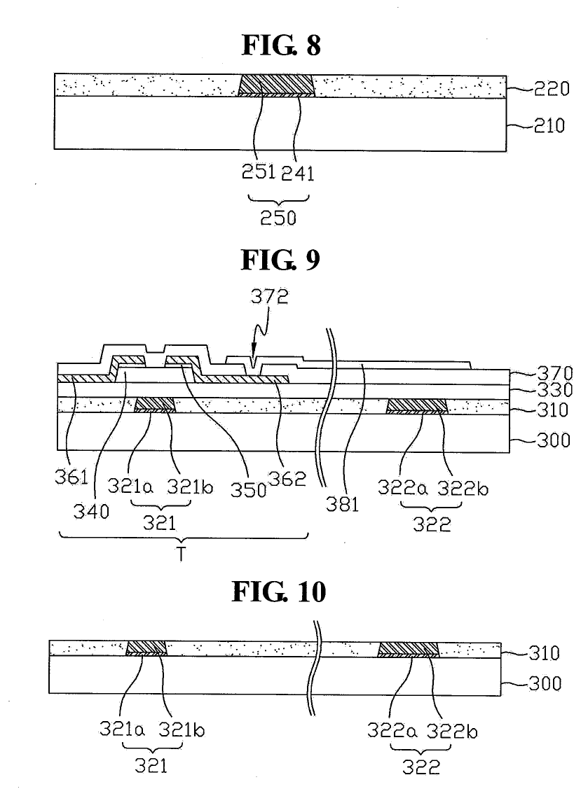

Referring to FIG. 8, after the lower organic layer 220 and the lower interconnection layer 241 are hardened through a heating process or a chemical process, an upper interconnection layer 251 is grown with a desired thickness on the lower interconnection layer 241 that functions as a seed layer through a plating process, so that a fairly thick interconnection line 250, which is composed of the lower interconnection layer 241 and the upper interconnection layer 251, is formed. In this case, the upper interconnection layer 251 is formed only on the lower interconnection layer 241 that functions as a seed layer, and is grown along the internal structure of the whole trench. The plating process may be an electroplating process or an electroless plating process.

As described above, in the second method of forming an interconnection line according to one or more embodiments of the present invention, since the upper organic layer 230 and the lower organic layer 220 are formed of a negative type photosensitive material, a trench having slopes that make the width of the trench become wider with increasing depth, or a trench of which the sloping angle of the sidewalls is almost 90°, may be formed. The trenches formed in the second method of forming an interconnection line according to one or more embodiments of the present invention have the following advantages. First, since the sidewall of the trench of the upper organic layer 230 that is directly exposed has the sloping angle of almost 90°, upper and lower parts of the trench of the upper organic layer 230 have the same width. Accordingly, the trench of the lower organic layer 220 may be formed with higher resolution. On the other hand, if the lower organic layer 220 is formed with a thickness that is as large as the thickness of the interconnection line 250, the width of the bottom part of the trench of the lower organic layer 220 may become too narrow. However, in the second method of forming an interconnection line according to one or more embodiments of the present invention, the width of the trench may become wider with increasing depth due to the characteristic of the negative type photosensitive material used, and thus the above-described problem can be solved. Also, since the width of the trench of the lower organic layer 220 becomes narrower in the direction of its opening, the edge build-up of the lower interconnection layer 241 formed on the bottom surface of the trench is suppressed, and thus the thickness of the upper interconnection layer 251 formed on the lower interconnection layer 241 is uniform. Accordingly, the subsequent laminated layers (not illustrated) can be grown more smoothly.

In the second method of forming an interconnection line according to one or more embodiments of the present invention, the width of the trench formed on the upper organic layer 230 made of a negative type photosensitive material may become wider or may be uniform in the depth direction. However, embodiment of the present invention is not limited thereto. In the case of the lower organic layer 220 made of a negative type photosensitive material, the trench formed on the lower organic layer 220 may have an inverse taper structure in which the width of the trench becomes wider in the depth direction, while in the case of the upper organic layer 230 made of a negative type photosensitive material, the trench formed on the upper organic layer 230 may have a forward taper structure in which the width of the trench becomes narrower in the depth direction.

In the first and second methods of forming an interconnection line according to one or more embodiments of the present invention as described above, the interconnection line is formed using two organic layers, that is, the lower organic layer 120 or 220 and the upper organic layer 130 or 230. However, embodiment of the present invention is not limited thereto. That is, the upper organic layer 130 or 230 is used as it is, but a lower inorganic layer may be used in place of the lower organic layer 120 or 220. In this case, by exposing a part of the lower inorganic layer through removal of a part of the upper organic layer 130 or 230 using an exposure process and a development process, and then etching the exposed lower inorganic layer using the upper organic layer 130 or 230 as an etching mask, trenches of specified depths may be formed in the upper organic layer 130 or 230 and the lower inorganic layer. Then, an interconnection line may be formed in the trench in substantially the same manner as that in the above-described embodiments of the present invention.

As described above in the first and second method of forming the interconnection line according to one or more embodiments of the present invention, since a relatively thick interconnection line is formed, the RC delay and the leakage current due to a decrease in the line width and an increase in the line length may be reduced, and thus a high-definition thin film transistor substrate may be manufactured.

Hereinafter, with reference to FIGS. 9 to 12, a method of manufacturing a thin film transistor substrate according to one or more embodiments of the present invention will be described in detail. For convenience in explanation, the method of manufacturing the thin film transistor substrate will be described with reference to the method of forming an interconnection line using a lower organic layer and an upper organic layer. However, embodiment of the present invention is not limited thereto, and as described above, the interconnection line may also be formed using a lower inorganic layer and an upper organic layer.

FIG. 9 is a sectional view of a thin film transistor substrate manufactured by a manufacturing method according to one or more embodiments of the present invention.

Referring to FIG. 9, the thin film transistor substrate includes a transparent insulating substrate 300, a thin film transistor T formed on the insulating substrate 300, a protective layer 370 formed on the thin film transistor T, and a pixel electrode 381 formed on the protective layer 370 and connected to the thin film transistor T through a contact hole 372. Although not illustrated in the drawing, a plurality of gate lines extending in a first direction and a plurality of data lines extending in a second direction are formed on the substrate 300.

A unit pixel is defined to include a region where the gate line and the data line cross each other and/or an adjacent region. In the unit pixel, the thin film transistor T and the pixel electrode 381 are formed, and a storage electrode 322 may be further formed. The thin film transistor T includes a gate electrode 321, an insulating layer 330, an active layer 340, an ohmic contact layer 350, a source electrode 361, and a drain electrode 362. Here, the gate electrode 321 is connected to the gate line, the source electrode 361 is connected to the data line, and the drain electrode 362 is connected to the pixel electrode 381 through the contact hole 372. Accordingly, if a specified gate signal transferred through the gate line is applied to the gate electrode 321, a conductive channel is formed in the active layer 340, and thus a specified data signal transferred through the data line is applied to the pixel electrode 381. The storage electrode 322 and the pixel electrode 381 formed on an upper part of the storage electrode 322 form both terminals of a storage capacitor, and the storage electrode 322 is connected to a storage line (not illustrated) extending roughly in parallel to the gate line to receive a reference voltage. Accordingly, the data signal charged on the pixel electrode 381 can be stably maintained through the storage capacitor until the next data signal is charged.

The gate electrode 321, the gate line, the storage electrode 322, and the storage line may be formed of the same material in the same step. In one or more embodiments of the present invention, the gate electrode 321, the gate line, the storage electrode 322, and the storage line may be formed using the first method of forming the interconnection line as described according to one or more embodiments of the present invention (with reference to FIGS. 1 to 4) and the second method of forming the interconnection line as described according to one or more embodiments of the present invention (with reference to FIGS. 5 to 8). That is, after a lower organic layer 310 and an upper organic layer (not illustrated) made of a positive or negative type photosensitive material are laminated, trenches are formed in the lower organic layer 310 and the upper organic layer, and interconnection lines composed of lower interconnection layers 321a and 322a and upper interconnection layers 321b and 322b, i.e. the gate electrode 321, the gate line, the storage electrode 322, and the storage line, are formed in the trenches through a lift-off process and a plating process. Accordingly, since the gate electrode 321, the gate line, the storage electrode 322, and the storage line are formed with a thickness that is as large as the thickness of the trenches to reduce the self resistance, any increase in the overall resistance of the interconnection line, generated due to a decrease in the line width of the interconnection line and an increase in the length of the interconnection line in order to comply with the requirement for a large-screen and high-definition liquid crystal display, can be offset.

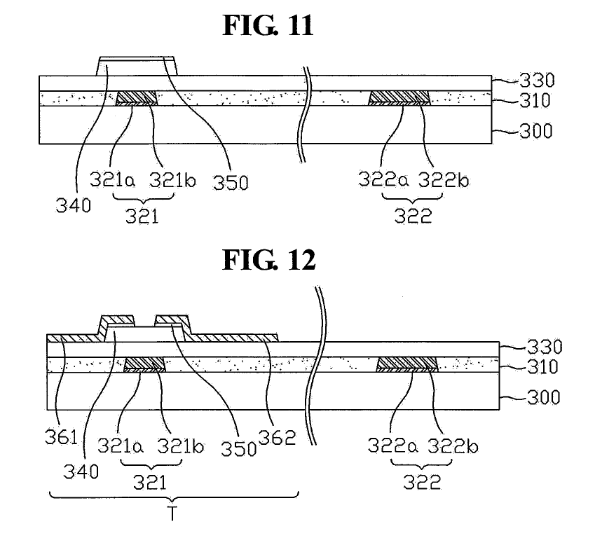

Hereinafter, with reference to FIGS. 10 to 12, a process of manufacturing a thin film transistor substrate according to one or more embodiments of the present invention will be described. Here, FIGS. 10 to 12 are sectional views explaining processes of a method of manufacturing a thin film transistor substrate according to one or more embodiments of the present invention.

First, referring to FIGS. 1 to 8, and 10, using the first method of forming the interconnection line as described according to one or more embodiments of the present invention (with reference to FIGS. 1 to 4) and the second method of forming the interconnection line as described according to one or more embodiments of the present invention (with reference to FIGS. 5 to 8), the interconnection lines composed of the lower interconnection layers 321a and 322a and the upper interconnection layers 321b and 322b, i.e. the gate electrode 321, the gate line, the storage electrode 322, and the storage line, are formed in the trench of the lower organic layer 310 on the substrate 300. That is, after the lower organic layer 310 and the upper organic layer (not illustrated) made of a positive or negative type photosensitive material are laminated, trenches are formed in the lower organic layer 310 and the upper organic layer, and the interconnection lines composed of the lower interconnection layers 321a and 322a and the upper interconnection layers 321b and 322b, i.e. the gate electrode 321, the gate line, the storage electrode 322, and the storage line, are formed in the trenches through a lift-off process and a plating process.

Referring to FIG. 11, an insulating layer 330 is formed on the resultant structure having the gate electrode 321 and the storage electrode 322; a semiconductor layer of a multilayer structure is formed by laminating in sequence an active layer 340 and an ohmic contact layer 350 on the insulating layer 330; and then an isolated island-shaped semiconductor layer is formed on the upper part of the gate electrode 321 by patterning the semiconductor layer of the multilayer structure. The insulating layer 330 may be made of an inorganic insulating material including at least one of silicon oxide (SiO₂) and silicon nitride (SiNx) having superior adhesion and insulation characteristics, and the active layer 340 may be made of an amorphous silicon (a-Si) layer. The ohmic layer 350 may be made of amorphous silicon doped with high-density silicide or n-type impurities (n+a-Si). At least one island-shaped semiconductor layer may be provided in each unit pixel.

Referring to FIG. 12, a conductive layer (not illustrated) for the data line is formed on the resultant structure having the island-shaped semiconductor layer, and a source electrode 361, a drain electrode 362, and a data line of desired shapes are formed by patterning the conductive layer. In this case, the conductive layer for the data line may be formed of at least one of Al, Mo, Cr, Ti, Ta, Ag, Cu, and Nd. Then, by removing the ohmic contact layer 350 exposed between the source electrode 361 and the drain electrode 362, at least one thin film transistor T, which includes the gate electrode 321, the insulating layer 330, the active layer 340, the ohmic contact layer 350, the source electrode 361, and the drain electrode 362, is formed in the unit pixel.

Referring again to FIG. 9, by forming the protective layer 370 on the resultant structure having the thin film transistor T and then patterning the protective layer 370, the contact hole 372 exposing a part of the drain electrode 362 is formed. Then, by forming a transparent conductive layer (not illustrated) on the resultant structure having the contact hole 372 and then patterning the conductive layer, the pixel electrode 381 connected to the drain electrode 362 that is exposed through the contact hole 372 is formed. The transparent conductive layer may be formed of ITO or IZO.

According to one or more embodiments of the present invention, since a thick gate line may be formed, the RC delay and the leakage current due to a decrease in the line width and an increase in the line length may be reduced, and thus a large-screen and high-definition thin film transistor substrate may be manufactured. Also, in one or more embodiments of the present invention, since the thin film transistor may be formed on a smoothed structure in which the gate line is formed in the trench of the lower organic layer 310, the whole process may be smoothly performed.

In one or more embodiments of the present invention as described, the gate electrode 321, the gate line, the storage electrode 322, and the storage line are formed using the method of forming the interconnection line using the lower organic layer 320 and the upper organic layer (not illustrated). However, embodiment of the present invention is not limited thereto, and the source electrode 361, the drain electrode 362, and the data line may be formed in the same manner as described in one or more embodiments of the present invention.

According to one or more embodiments of the present invention, the interconnection line buried in the trenches may be formed through one photo process, and thus the manufacturing process and cost may be reduced.

Also, according to one or more embodiments of the present invention, since the organic layer trench disperses the stress concentration due to increase in the interconnection thickness during forming of the interconnection line, a thick interconnection line may be formed and the warping of the substrate and the breakage of the thin film may be prevented.

Also, according to one or more embodiments of the present invention, when forming the upper and lower organic layers with negative type photosensitive organic materials, the trenches may be formed with higher resolution, and the edge build-up generated in the trench of the lower organic layer may be suppressed to improve the evenness of the interconnection line.

Although exemplary embodiments of the present invention have been described for illustrative purposes, those skilled in the art will appreciate that various modifications, additions and substitutions are possible without departing from the scope and spirit of the invention as disclosed in the accompanying claims. The exemplary embodiments should be considered in a descriptive sense only and not for purposes of limitation.

What is claimed is:

1. A method of forming an interconnection line, comprising:
preparing a substrate;
forming a lower organic layer and an upper organic layer on the substrate in lamination;
forming trenches in parts of the upper organic layer and the lower organic layer;
forming a lower interconnection layer in the trenches formed in parts of the lower organic layer;
removing the upper organic layer; and
filling the trenches formed in parts of the lower organic layer with an upper interconnection layer.

2. The method of claim 1, wherein the lower organic layer and the upper organic layer are formed of material that can be developed.

3. The method of claim 2, wherein the material for forming the lower organic layer has a higher development speed than a development speed of the material for forming the upper organic layer.

4. The method of claim 3, wherein the material for forming both the lower organic layer and the upper organic layer further comprises a positive type photosensitive material.

5. The method of claim 3, wherein the material for forming both the lower organic layer and the upper organic layer further comprises a negative type photosensitive material.

6. The method of claim 3, wherein the material for forming the lower organic layer further comprises a non-photosensitive material, and the material for forming the upper organic layer further comprises a photosensitive material.

7. The method of claim 3, wherein the material for forming the lower organic layer further comprises an acrylic resin, and the material for forming the upper organic layer further comprises a novolac resin.

8. The method of claim 1, wherein the forming of the trenches comprises:
forming a first trench by removing a part of the upper organic layer; and
forming a second trench by removing a part of the lower organic layer that is exposed through the first trench.

9. The method of claim 8, wherein the first trench has a width that is uniform.

10. The method of claim 8, wherein the first trench has a width that becomes wider with increasing depth.

11. The method of claim 8, wherein the second trench has a width that becomes wider with increasing depth.

12. The method of claim 8, wherein the first trench has a width that becomes narrower with increasing depth, and the second trench has a width that becomes narrower with increasing depth.

13. The method of claim 1, wherein the filling of the trenches formed in parts of the lower organic layer comprises plating the upper interconnection layer onto the lower interconnection layer formed on a bottom of the trenches.

14. A method of forming an interconnection line, comprising:
preparing a substrate;
forming a lower inorganic layer and an upper organic layer on the substrate in lamination;
forming trenches in parts of the upper organic layer and the lower inorganic layer;
forming a lower interconnection layer in the trenches formed in parts of the lower inorganic layer;
removing the upper organic layer; and
filling the trenches formed in parts of the lower inorganic layer with an upper interconnection layer.

15. A method of manufacturing a thin film transistor substrate, comprising:
preparing a transparent substrate;
forming a lower organic layer and an upper organic layer on the substrate in lamination;
forming trenches in parts of the upper organic layer and the lower organic layer;
forming a lower interconnection layer in the trenches formed in parts of the lower organic layer;
removing the upper organic layer;
filling the trenches formed in parts of the lower organic layer with an upper interconnection layer; and
forming a thin film transistor using the lower interconnection layer and the upper interconnection layer formed on the trenches as an interconnection line thereof.

16. The method of claim 15, wherein the lower organic layer and the upper organic layer are formed of material that can be developed.

17. The method of claim 16, wherein the material for forming the lower organic layer has a higher development speed than a development speed of the material for forming the upper organic layer.

18. The method of claim 17, wherein the material for forming both the lower organic layer and the upper organic layer further comprises a positive type photosensitive material or a negative type photosensitive material.

19. The method of claim 17, wherein the material for forming the lower organic layer further comprises a non-photosensitive material, and the material for forming the upper organic layer further comprises a photosensitive material.

20. The method of claim 15, wherein the forming of the trenches comprises:
forming a first trench by removing a part of the upper organic layer; and
forming a second trench by removing a part of the lower organic layer that is exposed through the first trench.

21. The method of claim 20, wherein the first trench has a width that is uniform.

22. The method of claim 20, wherein the first trench has a width that becomes wider with increasing depth.

23. The method of claim 20, wherein the second trench has a width that becomes wider with increasing depth.

24. The method of claim 15, wherein the filling of the trenches formed in parts of the lower organic layer comprises plating the upper interconnection layer onto the lower interconnection layer formed on a bottom of the trenches.
